(19) United States
(12) Patent Application Publication
(10) Pub. No.: US 2012/0207186 A1
(43) Pub. Date: Aug. 16, 2012

(54) TERAHERTZ QUANTUM CASCADE LASERS (QCLS)

(75) Inventors: Mikhail Belkin, Austin, TX (US); William Masselink, Berlin (DE)

(73) Assignee: The Board of regents of the University of Texas System, Austin, TX (US)

(21) Appl. No.: 13/148,459

(22) PCT Filed: Feb. 16, 2010
(86) PCT No.: PCT/US10/24322

§ 371 Date: May 4, 2012

Related U.S. Application Data
(60) Provisional application No. 61/152,824, filed on Feb. 16, 2009.

(51) Int. Cl. H01S 5/34

(52) U.S. Cl. 372/45.011

(57) ABSTRACT

Quantum cascade lasers (QCLs), and methods of manufacture of QCLs, comprising an active portion. In some embodiments, the active portion can comprise: a plurality of tensiley strained quantum barrier layers, each comprising Ga_{y}In_{1-y}As; and a plurality of compressively strained quantum well layers, each comprising GaₓIn₁₋ₓAs. In some embodiments, the active portion can comprise: a plurality of compressively strained quantum barrier layers, each comprising Al_{y}In_{1-y}As; and a plurality of tensiley strained quantum well layers, each comprising GaₓIn₁₋ₓAs. The active portion can be grown on InP substrate.

### BACKGROUND

The present application claims benefit of priority to U.S. Provisional Application Ser. No. 61/152,824, filed Feb. 16, 2009, which is incorporated by reference in its entirety.

1. Field of the Invention

The present invention relates generally to Quantum Cascade Lasers (QCLs), and, more particularly, but not by way of limitation, to QCLs with strained barrier layers (barriers) and/or strained well layers (wells).

2. Description of Related Art

A number of QCLs have been developed and/or are in use in the art. Emission wavelengths from some QCLs can include wavelengths in the mid infrared (MIR) with wavelengths less than 3 μm into the THz region with wavelengths longer than 200 μm. For MIR applications the (Al,Ga,In) As materials system lattice-matched to InP may be used (e.g., for telecommunication, lasers emitting near 1.55 μm). In this lattice-matched system, the conduction band discontinuity (ΔE_{C}) at the Al_{0.48}In_{0.52}As/Ga_{0.47}In_{0.53}As heterointerface is about 530 meV. This rather large value of AEI. can be advantageous for mid-infrared QCLs, and can allow laser emission at wavelengths as short as about 5 μm (photon energy is generally not larger than about 50% of AEI., and photon energy is generally related to the wavelength such that their product has a value of about 1240 meV×μm). To reach wavelengths shorter than 5 μm, (i.e., the range of 3-5 μm which may include absorption bands useful for molecular spectroscopy), the composition of both components can be changed so that the conduction band edge in the Al_{y}In_{1-y}As is increased and the conduction band edge in the GaₓIn₁₋ₓAs is decreased. Increasing the value of E_{c} in the Al_{y}In_{1-y}As can be accomplished by using values of y>0.48 while decreasing the value of E_{c} in the GaₓIn₁₋ₓAs can be accomplished by using values of x<0.47. This change in composition can result in the Al_{y}In_{1-y}As barriers being tensiley strained and the GaₓIn₁₋ₓAs wells being compressively strained.

A typical QCL active region contains several hundreds of well and barrier layers. To produce QCL active regions that do not suffer undesired effects due to the formation of low-dislocation defects, a strain-compensation technique can be used in which compressive strain in the GaₓIn₁₋ₓAs wells is compensated by tensile strain in the Al_{y}In_{1-y}As barriers, so that the net stress (force per unit area due to strain) is kept at or about zero. Currently, the Masselink group uses barriers with y=1 (pure AlAs) with GaₓIn₁₋ₓAs wells with x≈0.27 to achieve QCL emission with wavelengths as short as 3.0 μm. Some designs include pure InAs as a part of the structure. Internal strains in this system may be in excess of 3%, both compressively and tensiley, while maintaining sufficient crystalline quality for QCLs. (see, for example, W. T. Masselink, M. P. Semtsiv, S. Dressler, M. Ziegler, M. Wienold, “Physics, growth, and performance of (In,Ga)As—AlP/InP quantum-cascade lasers emitting at λ<4 μm,” Phys. Stat. Sol. B, 244, 2906-2915 (2007) and references therein).

THz QCLs, on the other hand, emit long wavelength, low-energy photons. For QCLs, the THz part of the spectrum may be considered to be between about 1 and 10 THz, with associated photon emission energies (and wavelengths) of between about 4 meV (300 μm) and 40 meV (30 μm). Because the emission energies for THz QCLs may be much smaller than for MIR QCLs, large values of AE, are not necessarily required. In fact, the large values of ΔE_{c} can be detrimental since the subband energies may depend sensitively on the well and barrier widths, which may cause difficulties in controlling the emission energy. Thus, many current THz QCLs are based on the AlₓGa₁₋ₓAs/GaAs system with rather small values of x. In such current THz QCLs, it is generally considered that the conduction band discontinuity should be limited to values 100<ΔE_{c}<150 meV. However, the electron effective mass, m_{eff}, in GaAs is larger than in (Ga,In)As. Since the gain in quantum cascade lasers scales as (m_{eff})^{-3/2}, where m_{eff} is the effective mass in quantum wells of a QCL structure (see, e.g., E. Benveniste, A. Vasanelli, A. Delteil, J. Dvenson, R. Teissier, A. Baranov, A. M. Andres, G. Strasser, I. Sagnes, and C. Sirtori, “Influence of the material parameters on quantum cascade devices, ” Appl. Phys. Lett. 93, 131108 (2008)), material systems with smaller electron effective masses in wells may be used to produce quantum cascade lasers with higher laser gain and, consequently, improved performance (e.g., higher operation temperature, and/or lower threshold current density).

The following references involve examples of QCLs, and may facilitate understanding of background information and possible application-specific information for this and related fields of endeavor: (1) U.S. Pat. No. 5,936,989, filed Apr. 29, 1997; (2) US Pat. No. 6,922,427, filed Aug. 28, 2001; (3) U.S. Pat. No. 7,386,024, filed Jul. 14, 2005; (4) U.S. patent application Ser. No. 11/204,971, filed Aug. 17, 2005, and published as Pub. No. U.S. 2006/0215718; (5) U.S. patent application Ser. No. 11/896,115, filed Aug. 29, 2007, and published as Pub. No. U.S. 2008/0219308. The foregoing references numbered (1) through (5) arc hereby incorporated by reference in their entireties.

### SUMMARY

The present disclosure describes, in part, certain improvements to quantum-cascade lasers (QCLs) emitting in the THz part of the spectral region. For example, the disclosure demonstrates that a strain-compensated (Al,Ga,In)As material system grown on InP (001) substrates can be advantageous compared to an (Al,Ga)As material system on

GaAs. In particular, the strain-compensated (Al,Ga,In)As material system grown on InP can allow arbitrarily small conduction band discontinuities between adjacent layers, and can result in smaller electron effective masses for both the well and barrier materials, compared to the (Al,Ga)As material system on GaAs.

“Tensiley strained,” as used in this disclosure, refers to a layer of material grown (e.g., pseudomorphically on a substrate) with a lattice con stant parallel to the substrate surface that is larger than the lattice constant of the same single-crystal material in its relaxed configuration, that is with strain ε>0. Similarly, “compressively strained,” as used in this disclosure, refers to an epitaxial layer of material grown (e.g., pseudomorphically on a substrate) with a lattice constant parallel to the substrate surface that is smaller than the lattice constant of the same single-crystal material in its relaxed configuration, that is with strain ε<0. Thus layers are tensiley strained when their relaxed lattice constant is smaller than that of the substrate and layers are compressively strained when their relaxed lattice constants are larger than that of the substrate.

The present disclosure includes various embodiments of quantum cascade lasers, and methods of manufacture.

Some embodiments of the present quantum cascade lasers, comprise: a substrate; and a strain-compensated active portion coupled to the substrate, the active portion comprising: a plurality of compressively strained quantum barrier layers, each comprising Al_{y}In_{1-y}As; and a plurality of tensiley strained quantum well layers, each comprising GaₓIn₁₋ₓAs.

In some embodiments, the plurality of quantum barrier layers and the plurality of quantum barrier layers are in a sequentially alternating configuration. In some embodiments, the substrate comprises InP. In some embodiments, in GaₓIn₁₋ₓAs, x is between about 0.50 and about 1, and in Al_{y}In_{1-y}As, y is selected to substantially compensate for strain in the GaₓIn₁₋ₓAs quantum well layers. In some embodiments, a conductive layer is coupled to the active region. In some embodiments, the conductive layer comprises a metal. In some embodiments, the conduction band discontinuity between the well layers and the barrier layers is in the range of about 0 meV to 400 meV. In some embodiments, the electron effective mass in the well layers is less than the electron effective mass of GaAs.

Some embodiments of the present quantum cascade lasers comprise: a substrate; and an active portion coupled to the substrate, the active portion comprising: a plurality of tensiley strained quantum barrier layers, each comprising Ga_{y}In_{1-y}As; and a plurality of compressively strained quantum well layers, each comprising GaₓIn₁₋ₓAs.

In some embodiments, the plurality of quantum barrier layers and the plurality of quantum barrier layers are in a sequentially alternating configuration. In some embodiments, the substrate comprises InP. In some embodiments, in GaₓIn₁₋ₓAs, x is between about 0 and about 0.46, and in Ga_{y}In_{1-y}As, y is selected to substantially compensate for strain in the GaₓIn₁₋ₓAs quantum well layers. In some embodiments, a conductive layer is coupled to the active region. In some embodiments, the conductive layer comprises metal. In some embodiments, the conduction band discontinuity between the well layers and the barrier layers is in the range of about 0 meV to 400 meV. In some embodiments, the electron effective mass in the well layers is less than the electron effective mass of GaAs. In some embodiments, the electron effective mass in the barrier layers is less than the electron effective mass of GaAs.

Any embodiment of any of the present methods can consist of or consist essentially of—rather than comprise/include/contain/have—any of the described steps, elements, and/or features. Thus, in any of the claims, the term “consisting of” or “consisting essentially of” can be substituted for any of the open-ended linking verbs recited above, in order to change the scope of a given claim from what it would otherwise be using the open-ended linking verb.

Details associated with the embodiments described above and others are presented below.

### BRIEF DESCRIPTION OF THE DRAWINGS

The following drawings illustrate by way of example and not limitation. For the sake of brevity and clarity, every feature of a given structure is not always labeled in every figure in which that structure appears. Identical reference numbers do not necessarily indicate an identical structure. Rather, the same reference number may be used to indicate a similar feature or a feature with similar functionality, as may non-identical reference numbers.

FIG. 1 depicts an embodiment of a Quantum Cascade Laser (QCL).

FIG. 2 depicts a chart of energy relative to position in one example of a Terahertz (THz) QCL.

FIG. 3 depicts the energies of the conduction band edges for Al_{y}In_{1-y}As and GaₓIn₁₋ₓAs strained on an InP substrate.

FIG. 4 depicts the absolute value of the ratio of barrier strain to well strain for several selected values of ΔE_{c} in a QCL active portion having compressively strained Al_{y}In_{1-y}As barriers and tensiley strained GaₓIn₁₋ₓAs wells.

FIG. 5 depicts the energies of the conduction band edges for GaₓIn₁₋ₓAs strained on an InP substrate.

FIG. 6 depicts the absolute value of the ratio of barrier strain to well strain for several selected values of ΔE_{c} in a QCL active portion having tensiley strained Ga_{y}In_{1-y}As barriers and compressively strained GaₓIn₁₋ₓAs wells.

FIG. 7 depicts the effective mass of electrons in the Γ valley minimum in strained layers of GaₓIn₁₋ₓAs on an InP substrate over a range of x.

FIG. 8 depicts the effective mass of electrons in the Γ valley minimum in strained layers of AlₓIn₁₋ₓAs on an InP substrate over a range of x.

### DESCRIPTION OF ILLUSTRATIVE EMBODIMENTS

The term “coupled” is defined as connected, although not necessarily directly, and not necessarily mechanically; two items that are “coupled” may be integral with each other. The terms “a” and “an” are defined as one or more unless this disclosure explicitly requires otherwise. The terms “substantially,” “approximately,” and “about” are defined as largely but not necessarily wholly what is specified, as understood by a person of ordinary skill in the art.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those elements. Likewise, a method that “comprises,” “has,” “includes” or “contains” one or more steps possesses those one or more steps, but is not limited to possessing only those one or more steps.

Further, a device or structure that is configured in a certain way is configured in at least that way, but it can also be configured in other ways than those specifically described.

Referring now to the drawings, and more particularly to FIG. 1 shown therein and designated by the reference numeral 10 is an embodiment of a Quantum Cascade Laser (QCL). QCL 10 may be interchangeably referred to herein as laser 10 or QCL 10. In the embodiment shown, laser 10 comprises a substrate 14, a first conductive layer 18, an active portion (region) 22, and a second conductive layer 26. In some embodiments, the substrate comprises indium phosphide (InP). In other embodiments, the substrate can comprise GaAs, (Ga,In)P, (Ga,In)P, Ge (lattice-matched to GaAs), Si (for use with nitrides), InAs, and/or GaSb. In the embodiment shown, laser 10 also comprises a conductive wire 30 in electrical communication with second conductive layer 26.

As shown, active portion 22 is coupled (e.g., indirectly) to substrate 14 by way of first conductive layer 18. In other embodiments, first conductive layer 18 may be omitted such that active portion 22 is coupled directly to substrate 14. First and second conductive layers 18 and 26 can comprise gold and/or any other suitable materials or components that permit laser 10 to function as described herein.

Active portion 22 comprises a plurality of layers (strata) of semiconductor material (a semiconductor superlattice). More specifically, active portion 22 comprises a plurality of quantum barrier layers (barriers) 34 (illustrated by darker lines), and a plurality of quantum well layers (wells) 38 (illustrated by lighter lines). In some embodiments, each barrier and/or each well may be composed of more than one material (e.g., composite barriers and/or composite wells). Additionally, in the embodiment shown, the plurality of quantum barrier layers and the plurality of quantum well layers are in a sequentially alternating configuration (e.g., quantum well layer 38, quantum barrier layer 34, quantum well layer 38, quantum barrier layer 34, and so on). In addition to certain specific embodiments described below, some embodiments of the present QCLs can comprise compressively strained (Al,In)P barrier layers and tensiley strained (Ga,In)P well layers; tensiley strained (Ga,In)P barrier layers and compressively strained (Ga,In)P well layers; and/or Si subtrates with nitride-based well and barrier layers.

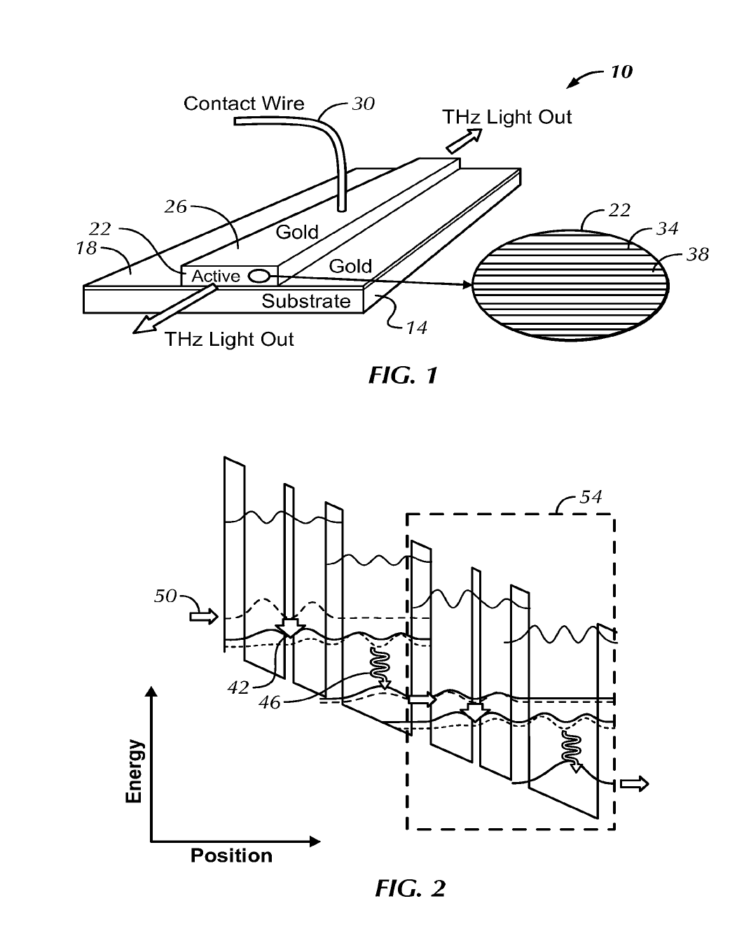

As will be appreciated by those of ordinary skill in the art, laser 10 is configured to permit an electrical current to pass through active portion 22 such that electrons flow through the active portion and emit light (photons) as they pass from higher to lower energy levels. Stated another way, as an electron travels across the active portion, it “sees” a sequence of potential wells and barriers as generally illustrated in FIG. 2. As a result, the electron wavefunction generally becomes localized to energy levels corresponding to a particular superlattice configuration. The energy levels create laser action in these devices as current is sent through the active region.

FIG. 2 depicts a general chart of energy relative to position in the active portion of one example of a Terahertz (THz) QCL reported in [M. A. Belkin et al., Optics Express 16, 3242 (2008)]. Vertical arrows 42 illustrate photon emission, wavy arrows 46 illustrate phonon emission, and horizontal arrows 50 illustrate the direction of the electron transport (which is perpendicular to the semiconductor layers in laser 10 in FIG. 10). A single quantum-cascade module or cascade (one quantum well layer and one quantum barrier layer) is bounded by a box 54. As an example for reference, a 10 μm-thick active region utilizing a GaAs/Al_{0.15}Ga_{0.85}As material system can consist of 226 modules or cascades.

Various embodiments of the present quantum cascade lasers may take advantage of the small electron effective mass in (Ga,In)As for THz QCLs, and may overcome or compensate for the possible disadvantages of large AE, values by using strain compensation. Applying what may be known in the art as the Matthews-Blakeslee calculation to the presently described embodiments, it may be desirable to keep the maximum absolute value of the allowed strain integrated over thickness to less than about 7.5% nm to avoid the formation of dislocations (see Matthews J W and Blakeslee A E 1974 J. Cryst. Growth 27 118). The disadvantages of large AE, values can include larger inhomogeneous emission linewidth broadening, (see, e.g., J. B. Khurgin, “Inhomogeneous origin of the interface roughness broadening of intersubband transitions,” Appl. Phys. Lett. 93, 091104 (2008) and the references therein), as well as larger interface roughness scattering, (see, e.g., S. Tsujino, A. Borak, E. Muller, M. Scheinert, C. V. Falub, H. Sigg, D. Grutzmacher, M. Giovanni, J. Faist, “Interface-roughness-induce broadening of intersubband electroluminescence in p-SiGe and n-GalnAs/AllnAs quantum-cascade structures,” Appl. Phys. Lett. 86, 062113 (2005) and the references therein).

Various material systems are described in more detail below for use in active portions (regions) of various embodiments of quantum cascade lasers, including, for example, the embodiment depicted in FIG. 1. For example, two specific InP-based material systems for THz QCLs include: 1) Al_{y}In_{1-y}As/GaₓIn₁₋ₓAs with compressively strained Al_{y}In_{1-y}As barriers and tensiley strained GaₓIn₁₋ₓAs wells, and 2) Ga_{y}In_{1-y}As/GaₓIn₁₋ₓAs with tensiley strained Ga_{y}In_{1-y}As barriers and compressively strained GaₓIn₁₋ₓAs wells.

### Al_{y}In_{1-y}As/GaₓIn₁₋ₓAs Material System

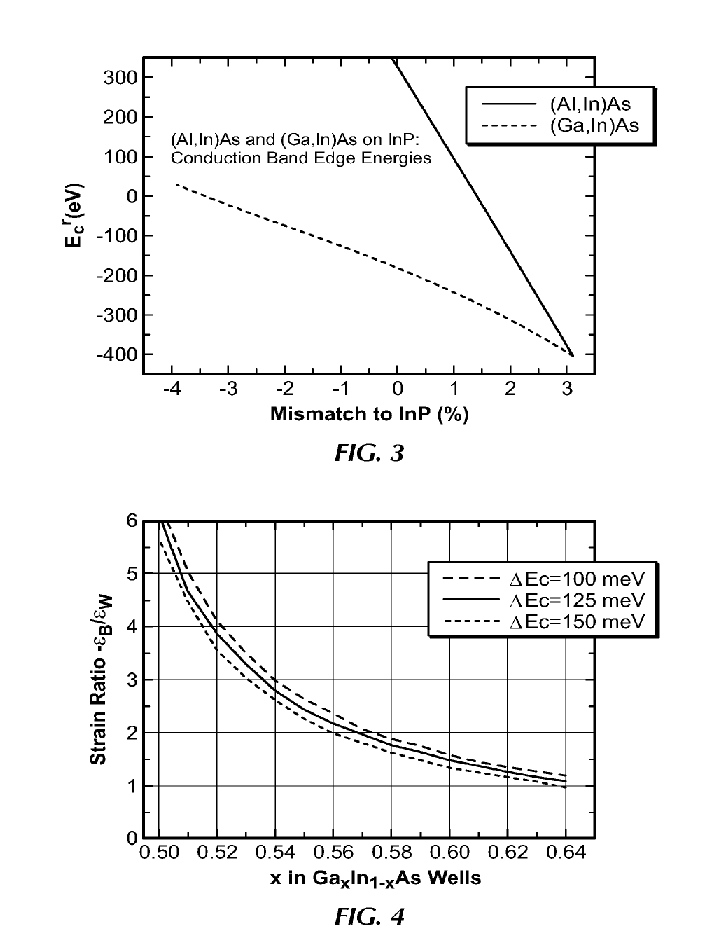

This system uses compressively strained Al_{y}In_{1-y}As quantum barrier layers (barriers) and tensiley strained GaₓIn₁₋ₓAs quantum well layers (wells) oppositely strained as compared to the short-wavelength MIR system that is described in the background section above. FIG. 3 depicts the energies of the conduction band edges for Al_{y}In_{1-y}As and GaₓIn₁₋ₓAs strained on an InP substrate. Compressively straining the Al_{y}In_{1-y}As lowers the conduction band edge of the barriers. Conversely, tensiley straining the GaₓIn₁₋ₓAs raises the conduction band edge of the wells. As illustrated in FIG. 3, by using tensiley strained GaₓIn₁₋ₓAs wells (region of the lower (Ga,In)As curve more to the left) with compressively strained Al_{y}In_{1-y}As barriers (region of upper (Al,In)As curve more to the right), the value of ΔE_{c} can be made arbitrarily small (or even negative). The compressively strained barriers and tensiley strained wells can allow a small ΔE_{c} in this system. For example, in some embodiments, ΔE_{c} is about 100 meV, which allows emission of light with a wavelenth in the terahertz range.

In some embodiments of the Al_{y}In_{1-y}As/GaₓIn₁₋ₓAs material system for THz QCLs, the well layers (wells) are relatively thick, e.g., ˜50-200 Angstroms, such that it can be beneficial for the strain in the wells to be relatively smaller. Thus, the value of the strain in the barriers can be larger than the value of the strain in the wells so that thin barriers can be used with thicker wells. The ratio of total well thickness to total barrier thickness in one module or cascade (e.g. of FIG. 2) of the present THz QCLs can be in the range of η=1-6. To produce strain-compensated QCL structure, the well strain should be opposite in sign and 1/η in magnitude, relative to the barrier strain.

FIG. 4 depicts the absolute value of the ratio of barrier strain to well strain for several selected values of ΔE_{c}. As illustrated, using wells composed of GaₓIn₁₋ₓAs with about 0.50<x<0.64 results in a modest strain of ε_{W}<1.26% that can be compensated for by strains in the Al_{y}In_{1-y}As barriers of −ε_{B}≈1-3%. If the compressive strain in the Al_{y}In_{1-y}As barriers is compensated by the tensile strain in the GaₓIn₁₋ₓAs wells, the net stress (and strain) can be kept at or about zero and the strain-compensated active region can be repeated as often as desired. The net strain is the accumulated strain due to compressively strained layers and tensiley strained layers. Strain compensation can be used decrease net strain by compensating compressively strained layers with tensiley strained layers. If strain accumulates because it is not compensated, the (superlattice) crystal may dislocate, which may result in defects that prevent high efficiency optical transitions and/or prevent laser action altogether.

It should be noted that in the Al_{y}In_{1-y}As/GaₓIn₁₋ₓAs material system, ΔE_{c} may depend strongly on the barrier composition y, such that small variations in the composition may noticeably affect performance. The level of control of barrier composition y is likely similar to that required for the MIR QCLs described above in the background section, such that one of ordinary skill in the art will be able to control the composition to thereby achieve a desired ΔE_{c}.

### Ga_{y}In_{1-y}As/GaₓIn₁₋ₓAs Material System

With this material system, both barriers and wells are composed of (Ga,In)As, but with differing compositions. More specifically, this material system can use tensiley strained Ga_{y}In_{1-y}As quantum barrier layers (barriers) and compressively strained GaₓIn₁₋ₓAs quantum well layers (wells). The tensiley strained barriers and compressively strained wells can allow a small ΔE_{c} in this system while maintaining an electron effective mass significantly smaller than that of GaAs. For example, in some embodiments, ΔE_{c} is about 100 meV, which allows emission of light with a wavelength in the THz range.

As described above, the ratio of total well thickness to total barrier thickness in one module or cascade (e.g. of FIG. 2) of the present THz QCLs can be in the range of η=1-6. To produce strain-compensated QCL structure, the well strain should be opposite in sign and 1/η in magnitude, relative to the barrier strain.

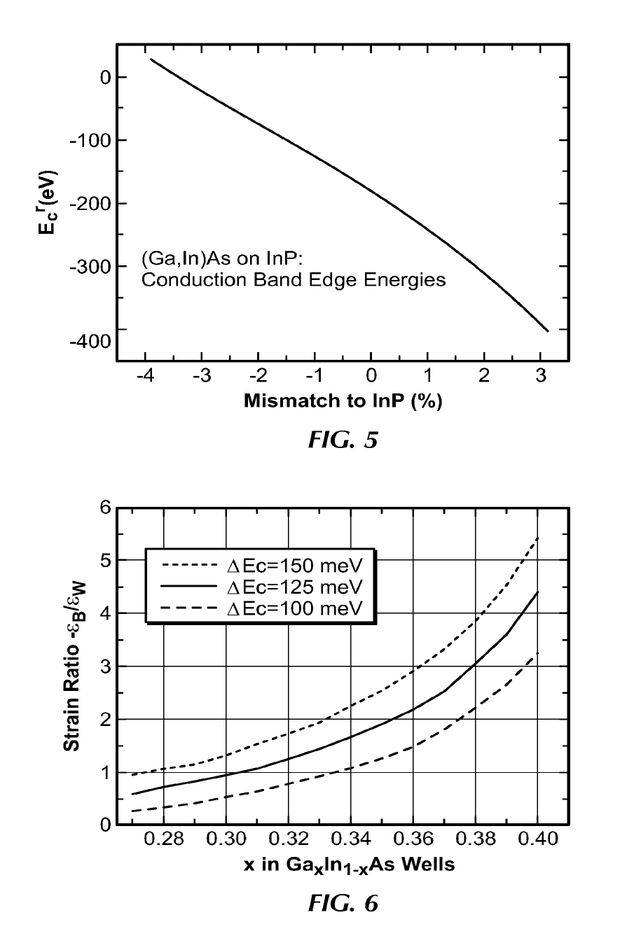

FIG. 5 depicts the energies of the conduction band edges for GaₓIn₁₋ₓAs strained on an InP substrate. As illustrated, arbitrarily small values of ΔE_{c} can be achieved when the compositions are arbitrarily similar to each other. In contrast, values of ΔE_{c} as large as ΔE_{c}≈400 meV could be possible using a GaAs/InAs material system.

Though the various embodiments of the present invention are not limited to any particular range of values for ΔE_{c}, values of ΔE_{c} in the range of 100<ΔE_{c}<150 meV can be achieved, for example, while simultaneously keeping the strain in the well small enough to grow thick wells, with a range of well-material compositions of about 0.28<x<0.40, with strain in the range of 0.3<ε_{w}<1.3%. The resulting barriers strains can be kept −ε_{B}<2%.

This Ga_{y}In_{1-y}As/GaₓIn₁₋ₓAs material system has the added advantage that the strain and conduction band discontinuities are relatively less sensitive to variations in compositions, thereby improving consistency or repeatability of the laser performance produced with this material system, increasing the accuracy of structure growth, and/or resulting in higher predictability of the emission wavelength.

Manufacture of Ga_{y}In_{1-y}As/GaₓIn₁₋ₓAs heterostructures can be achieved by various methods, such as, for example, by using two different In sources in a gas-source molecular-beam epitaxy (MBE) system, solid-source MBE system, chemical vapor deposition system, and/or the like.

### Electron Effective Masses

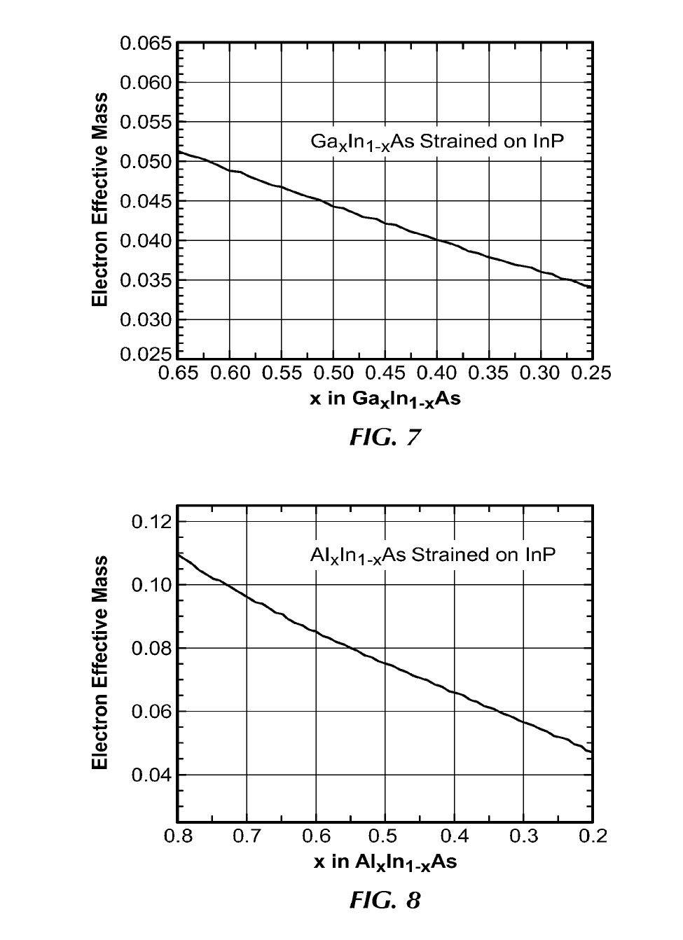

A benefit some embodiments of the present material systems is to achieve smaller electron effective masses than has been possible in traditional (Al,Ga)As/GaAs material systems. For example, both of the strain-compensated material systems disclosed herein have quantum well layers (wells) comprising GaₓIn₁₋ₓAs with compositions similar to the compositions of lattice-matched (Ga,In)As. FIG. 7 depicts the effective mass of electrons in the F valley minimum in GaₓIn₁₋ₓAs over a range of x which corresponds to various possible material compositions for wells in the present QCLs. The electron effective masses in the proposed materials are significantly smaller that that in GaAs/AlGaAs system, where they are 0.067 of electron effective mass (in GaAs) or larger (in AlGaAs). Since the electronic wavefunctions are to a considerable extent also in the barrier material, it can be advantageous that the electron effective mass in Al_{y}In_{1-y}As is also not too large over the range of y depicted in FIG. 8.

The various illustrative embodiments of devices, systems, and methods described herein are not intended to be limited to the particular forms disclosed. Rather, they include all modifications, equivalents, and alternatives falling within the scope of the claims.

The claims are not intended to include, and should not be interpreted to include, means-plus- or step-plus-function limitations, unless such a limitation is explicitly recited in a given claim using the phrase(s) “means for” or “step for,” respectively.

1. A quantum cascade laser, comprising:
a substrate; and
a strain-compensated active portion coupled to the substrate, the active portion comprising:
a plurality of compressively strained quantum barrier layers, each comprising Al_{y}In_{1-y}As; and
a plurality of tensiley strained quantum well layers, each comprising GaₓIn₁₋ₓAs.

2. The quantum cascade laser of claim 1, where the plurality of quantum barrier layers and the plurality of quantum barrier layers are in a sequentially alternating configuration.

3. The quantum cascade laser of any of claims 1-2, where the substrate comprises InP.

4. The quantum cascade laser of any of claims 1-3, where in GaₓIn₁₋ₓAs, x is between about 0.50 and about 1, and in Al_{y}In_{1-y}As, y is selected to substantially compensate for strain in the GaₓIn₁₋ₓAs quantum well layers.

5. The quantum cascade laser of any of claims 1-4, where a conductive layer is coupled to the active region.

6. The quantum cascade laser of claim 5, where the conductive layer comprises a metal.

7. The quantum cascade laser of claim 1, where the conduction band discontinuity between the well layers and the barrier layers is in the range of about 0 meV to 400 meV.

8. The quantum cascade laser of claim 1, where the electron effective mass in the well layers is less than the electron effective mass of GaAs.

9. A quantum cascade laser, comprising:
a substrate; and
an active portion coupled to the substrate, the active portion comprising:
a plurality of tensiley strained quantum barrier layers, each comprising Ga_{y}In_{1-y}As; and
a plurality of compressively strained quantum well layers, each comprising GaₓIn₁₋ₓAs

10. The quantum cascade laser of claim 9, where the plurality of quantum barrier layers and the plurality of quantum barrier layers are in a sequentially alternating configuration.

11. The quantum cascade laser of any of claims 10, where the substrate comprises InP.

12. The quantum cascade laser of any of claims 9-11, where in Gaₓn₁₋ₓAs, x is between about 0 and about 0.46, and in Ga_{y}In_{1-y}As, y is selected to substantially compensate for strain in the GaₓIn₁₋ₓAs quantum well layers.

13. The quantum cascade laser of any of claims 9-12, where a conductive layer is coupled to the active region.

14. The quantum cascade laser of claim 13, where the conductive layer comprises metal.

15. The quantum cascade laser of any of claims 9-14, where the conduction band discontinuity between the well layers and the barrier layers is in the range of about 0 meV to 400 meV.

16. The quantum cascade laser of any of claims 9-15, where the electron effective mass in the well layers is less than the electron effective mass of GaAs.

17. The quantum cascade laser of claim 16, where the electron effective mass in the barrier layers is less than the electron effective mass of GaAs.
